(19) United States
(12) Patent Application Publication
(10) Pub. No.: US 2011/0042672 A1
(43) Pub. Date: Feb. 24, 2011

(54) Coplanar waveguide having amorphous silicon layer between substrate and insulated layer and a manufacturing method thereof

(75) Inventor: Takehiko Makita, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/805,749

(22) Filed: Aug. 18, 2010

(30) Foreign Application Priority Data
Aug. 20, 2009 (JP) 2009-190981

(51) Int. Cl. H01L 29/12; H01L 21/02

(52) U.S. Cl. 257/51; 438/47; 438/96; 257/E21.002; 257/E29.068

(57) ABSTRACT

A coplanar waveguide includes a high resistance silicon substrate having one primary surface on which an amorphous silicon layer is formed, an insulated layer formed on the amorphous silicon layer, a signal line arranged on the insulated layer and a pair of ground planes arranged on the insulated layer so as to put the signal line between the planes. The coplanar waveguide is not structured as conventionally having a thick insulated layer formed on a single-crystalline silicon substrate, thereby reducing attenuation otherwise caused by leakage of electromagnetic wave in a frequency bandwidth of millimeter wave.

### BACKGROUND OF THE INVENTION

1. Field of the Invention

The present invention relates to a coplanar waveguide, particularly for use in a connection between integrated circuit chips operating on a frequency bandwidth for millimeter wave or between an integrated circuit chip and the coaxial connector of an integrated circuit package. The present invention also relates to a method for manufacturing such a coplanar waveguide.

2. Description of the Background Art

Conventionally, a coplanar waveguide for use in a communication on a frequency bandwidth for millimeter wave may generally be configured to have a metal wiring pattern formed on a crystalline compound semiconductor substrate, such as GaAs or InP substrate. Since such a crystalline substrate has its specific resistance as high as the order of about 10⁷ Ω·cm, a coplanar waveguide, when formed on a crystalline compound semiconductor substrate, allows the leakage of electromagnetic wave onto the substrate to be reduced.

Accordingly, the crystalline compound semiconductor substrate can be applied to implementing a monolithic microwave integrated circuit (MMIC) for use in a high frequency bandwidth of 10 GHz or more. For instance, the crystalline compound semiconductor substrate can be provided with an active device, such as a transistor or a mixer, a transmission line serving as an impedance matching circuit on the input and output sides of the active device, and a passive device, such as a filter or an inductor.

However, the crystalline compound semiconductor substrate is more expensive than the single-crystalline silicon substrate. Crystalline compound semiconductor substrates predominantly available on the market have the size of three to four inch in diameter. By contrast, single-crystalline silicon substrates predominantly have the size of six inch or more in diameter. The crystalline compound semiconductor substrate, thus higher in cost and smaller in available size, results in higher cost for manufacturing the coplanar waveguide formed on this substrate.

Now, a type of coplanar waveguide is known which has a single-crystalline silicon substrate having its specific resistance of about 1 to 10 kΩ·cm on which formed is an insulating film, such as silicon dioxide film, silicon nitride film or polyimide film, having its thickness of 10 μm or more with a signal line and a ground plane formed on the insulating film, as disclosed, for instance, in Japanese patent laid-open publication No. 2000-68714. In such a coplanar waveguide, although a single-crystalline silicon substrate is applied as the substrate, it is possible to reduce the leakage of electromagnetic wave onto the substrate, and therefore, to implement an MMIC for use in a high frequency bandwidth of 10 GHz or more.

The insulating film in the coplanar waveguide as disclosed by the above-mentioned '714 publication however has its thickness of 10 μm or more. When the silicon oxide or silicon nitride film is formed as the insulating film by using plasma chemical vapor deposition (CVD) equipment being usable by the inventor, it took four to twenty hours to form the insulating film with a thickness of 10 μm. It is thus unfeasible to form the insulating film in the plasma CVD manner.

In accordance with experiments by the inventor, it was understandable that the insulating film with a thickness of 0.2 to 2 μm brings an attenuation constant deteriorated to 1 dB/mm or more for frequency of 1 to 30 GHz. This is caused by a low resistance layer with specific resistance of about 0.01 Ω·cm formed on the interface between the insulating film, such as silicon oxide or silicon nitride film, and the single-crystalline silicon substrate with high specific resistance (often referred to as a high resistance silicon substrate). In order to prevent the effect of the low resistance layer, the insulating film requires its thickness of about 10 μm.

### SUMMARY OF THE INVENTION

As a result of succeeding diligent research by the inventor, it is understandable that a high resistance silicon substrate having its one main surface on which an amorphous silicon layer is formed which has an insulating film formed thereon can cause the deterioration of an attenuation constant to be reduced although the thickness of the insulating film is thinner than 10 μm.

It is an object of the present invention to provide a coplanar waveguide that is capable of reducing attenuation otherwise caused by leakage of electromagnetic wave onto the substrate in a frequency bandwidth of millimeter wave. It is another object of the invention to provide a method for producing such a coplanar waveguide.

In accordance with the present invention, a coplanar waveguide comprises a high resistance silicon substrate having one primary surface on which an amorphous silicon layer is formed, an insulated layer formed on the amorphous silicon layer, a signal line arranged on the insulated layer and a pair of ground planes arranged on the insulated layer so as to put the signal line between the planes.

Also in accordance with the present invention, a method of fabricating a coplanar waveguide comprises the steps of forming an amorphous silicon layer on one primary surface of a high resistance silicon substrate, forming an insulated layer on the amorphous silicon layer, and arranging a signal line and a pair of ground planes on the insulated layer so as to put the signal line between the planes.

According to the coplanar waveguide of the present invention, since the amorphous silicon layer is formed on the high resistance silicon substrate and the insulated layer is formed on the amorphous silicon layer, it is possible to prevent the interface between the high resistance silicon substrate and the insulating film from serving as a low resistance layer to thereby reduce a deterioration of an attenuation constant.

The inventive concept disclosed in the application may also be defined in ways other than in the claims presented below. The inventive concept may consist of several separate inventions particularly if the invention is considered in light of explicit or implicit subtasks or from the point of view of advantages achieved. In such a case, some of the attributes included in the claims may be superfluous from the point of view of separate inventive concepts. Within the framework of the basic inventive concept, features of different embodiments are applicable in connection with other embodiments.

### BRIEF DESCRIPTION OF THE DRAWINGS

The objects and features of the present invention will become more apparent from consideration of the following detailed description taken in conjunction with the accompanying drawings in which:

FIG. 1 is a schematic cross-sectional view of a coplanar waveguide in accordance with a preferred embodiment of the present invention;

FIG. 2 shows as an example the transmission electron microscope (TEM) image of an end elevational section around the surface of a substrate of the coplanar waveguide;

FIG. 3A is a top plan view illustrating the preferred embodiment shown in FIG. 1 in order to understand an examination of the coplanar waveguide;

FIG. 3B is a schematic block diagram showing an examining system for the coplanar waveguide in order to understand an examination of the coplanar waveguide;

FIG. 4 is a graph plotting curves of attenuation constant with respect to frequency in the coplanar waveguide of the preferred embodiment;

FIG. 5 is a schematic cross-sectional view, like FIG. 1, of a coplanar waveguide in accordance with an alternative embodiment of the present invention;

FIGS. 6A to 6E schematically show the steps of manufacturing the coplanar waveguide of the alternative embodiment in schematic cross-sectional views;

FIG. 7 is a graph plotting curves of attenuation constant with respect to frequency in the coplanar waveguide of the alternative embodiment; and

FIG. 8 is a graph plotting curves of attenuation constant with respect to frequency in the coplanar waveguide of a further alternative embodiment.

### DESCRIPTION OF THE PREFERRED EMBODIMENTS

Preferred embodiments of the present invention will now be described with reference to the accompanying drawings. Those figures schematically illustrate the positional relationship between each composing element and other matters merely in order to assist the reader in understanding the present invention. Materials and numerical conditions of constituent elements or other factors of preferred embodiments, described below, are just illustrative. Therefore, the present invention is not to be understood as restrictive by those embodiments. The embodiments can be changed or modified so as to accomplish the advantageous effects of the present invention without departing from the scope and spirit of the present invention.

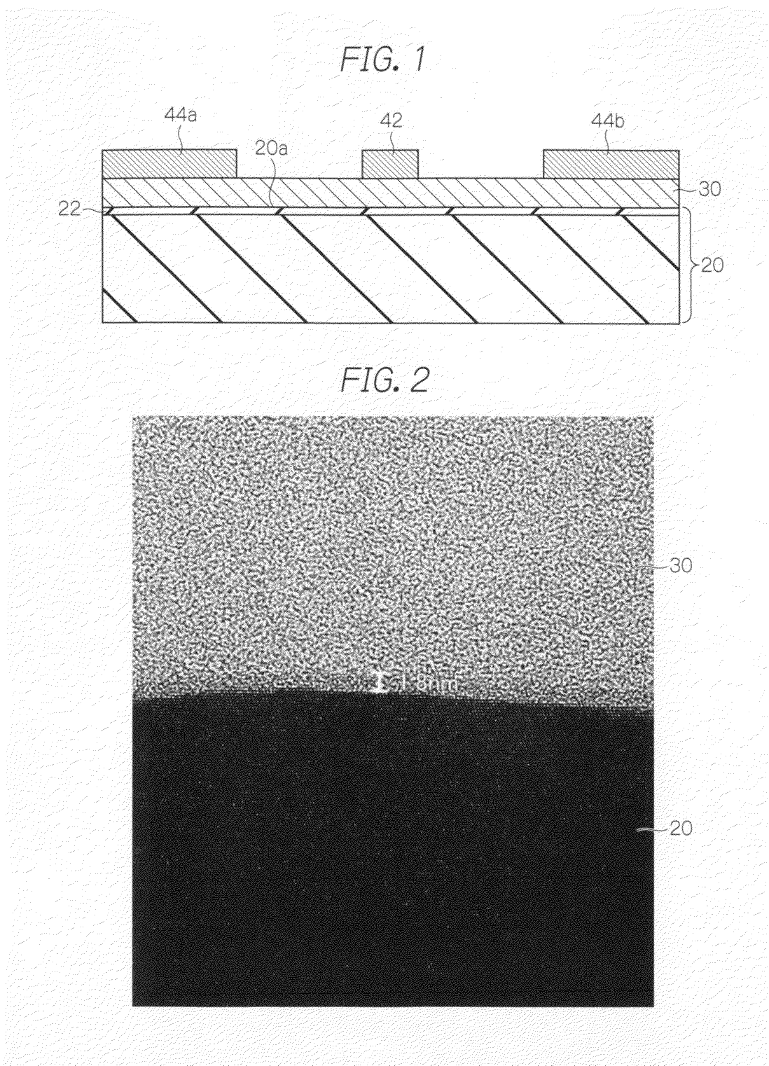

With reference first to FIG. 1, a preferred embodiment of a coplanar waveguide 10 according to the present invention will be described below about its configuration and fabrication method. FIG. 1 is a schematic cross-sectional view illustrating the coplanar waveguide of the preferred embodiment, which shows a cross-section perpendicular to the longitudinal direction of the waveguide.

The coplanar waveguide 10 generally includes a generally flat semiconductor substrate 20, an insulating film 30 formed over the substrate, and a signal line 42 and a pair of ground planes 44 or 44a and 44b formed on the insulating film.

The substrate 20 may be of a single-crystalline silicon with high specific resistance, and may sometimes be referred to as a high resistance silicon substrate. In the embodiment, the specific resistance of the high resistance silicon substrate may be from 1 kΩ·cm to 10 kΩ·cm, inclusive.

The substrate 20 is of a generally flat board having opposite main surfaces, one of which 20a has an amorphous silicon layer 22 formed thereon. The amorphous silicon layer 22 may be formed, for instance, with a thickness of 1 to several nm.

The amorphous silicon layer 22 can be formed by damaging the main surface 20a of the substrate 20 with ion bombardment. The amorphous silicon layer 22 may be formed, for instance, by a reactive ion etching (RIE) using sulfur hexafluoride (SF₆) gas. By carrying out the RIE process using SF₆ gas for two minutes, it is possible to obtain the amorphous silicon layer 22 with a thickness of 1.8 nm.

FIG. 2 shows the image of an end elevational section around the surface of a silicon substrate damaged by the RIE process, which is taken by means of a transmission electron microscope (TEM). In FIG. 2, there are shown the substrate 20 and the electrically insulating film 30 and, in the surface of the substrate 20 on the insulating film 30 side, the amorphous silicon layer is formed with a thickness of 1.8 nm.

The insulating film 30 is formed on the main surface 20a of the substrate 20, namely, on the amorphous silicon layer 22.

The insulating film 30 may be fabricated by any suitable methods, such as conventional plasma or heat chemical vapor deposition (CVD), in the form of SiO₂, SiN or SiON film.

The insulating film 30 may advantageously have its film thickness to the extent that the signal line 42 and the ground planes 44 are insulated from the substrate 20, e.g. a thickness of 100 nm or more. Since the thicker insulating film 30 causes the stronger stress on the film, it is preferable that the insulating film 30 is formed with a thickness of 2 μm or less. In the embodiment, the insulating film 30 may be fabricated in the form of SiN film having a thickness of 200 nm.

If the insulating film 30 is fabricated in the form of SiO₂ or SiON film, a very thin film of SiN having a thickness of about 20 nm may advantageously be formed on the SiO₂ or SiON film in order to enhance the adhesive force of the insulating film with the signal line 42 and the ground planes 44. It is therefore preferable that the insulating film 30 is fabricated in the form of SiN film or, alternatively, of either SiO₂ or SiON film layered with SiN film.

The signal line 42 is mounted on the insulating film 30. A pair of ground planes 44 is also mounted on the insulating film 30 so that the signal line 42 is arranged between the planes.

The signal line 42 and the ground planes 44 may be formed by a conventional process, such as photolithography or plating.

In such a process, first, resist material, e.g. photoresist, is applied to the insulating film 30. The photoresist layer is then exposed and developed to remove parts of the photoresist which will have the signal line 42 and the ground planes 44 to be formed, thereby forming resist patterns for the coplanar waveguide. Furthermore, onto the entire resist and film, a metal film is layered by, for instance, plating process. The metal film may be formed by plating with gold or Au, i.e. by gliding.

Subsequently, the remaining resist patterns are removed by using organic solvent to thereby complete the signal line 42 and the ground planes 44.

In a high frequency bandwidth, electromagnetic waves are conducted by the skin effect only in the vicinity of the surface of a conductor. In order to reduce the electrical resistance of a signal line or to secure the current density necessary for a signal line functioning also as power feed, the signal line requires a film thickness of about several μm. Therefore, for forming a signal line, the plating process may be more advantageously utilized.

The illustrative embodiment utilizes the high resistance silicon substrate having the amorphous silicon layer on which the insulated layer is formed as SiN or SiO₂ film. SiN or SiO₂ film can thus avoid direct contact with the single-crystalline silicon. The amorphous silicon has its energy band gap ranging from 1.4 to 1.8 eV which is broader than the single-crystalline silicon having its energy band gap of 1.1 eV. Considerably, this suppresses the energy band of the single crystalline silicon from bending, and consequently, a low resistance layer will not be caused.

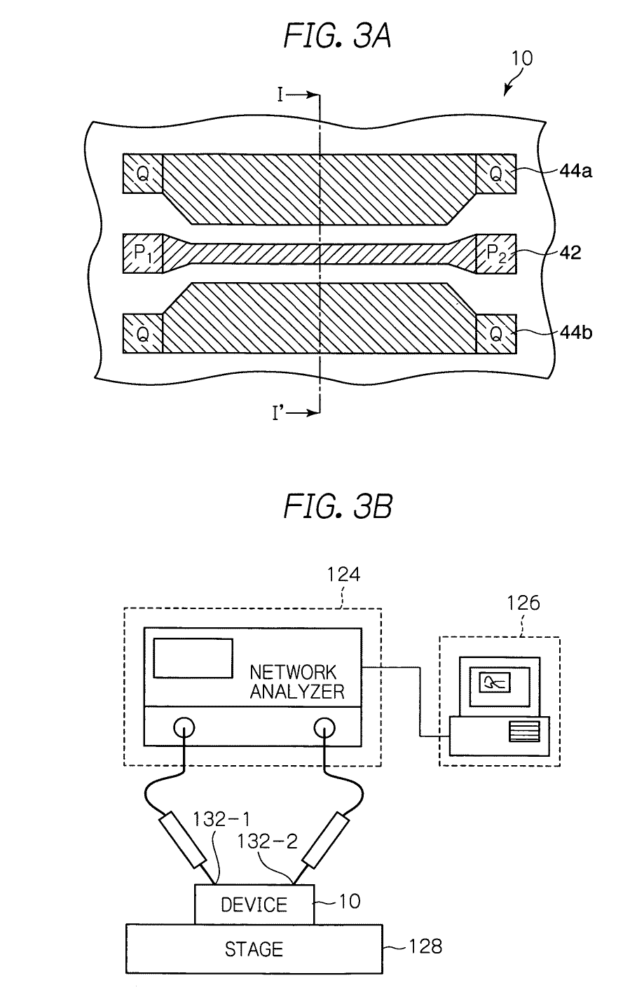

Next, a manner of examining the coplanar waveguide will be described with reference to FIGS. 3A and 3B. FIG. 3A is a top plan view illustrating the coplanar waveguide 10 of the illustrative embodiment shown in FIG. 1 on its primary surface side. FIG. 1 corresponds to the cross-sectional view cut along a line I-I′ in FIG. 3A.

FIG. 3B is a schematic block diagram showing an examining system for detecting scattering parameters or S parameters as a small-signal property of the coplanar waveguide.

The layout pattern of the coplanar waveguide 10 has the signal line 42 and the pair of ground planes 44a and 44b arranged on the substrate surface so as to put the signal line between the planes. The signal line 42 has its opposite ends respectively including first and second ports P₁ and P₂ as contact pads. Similarly, each ground plane 44 has its opposite ends including respective grounding ports Q as contact pads.

As shown in FIG. 3A, the signal line 42 runs substantially in parallel with the ground planes 44a and 44b. The signal line 42 may keep substantially equal spacing with respect to the ground planes 44a and 44b. The coplanar waveguide also may be symmetrical in pattern with respect to the longitudinal direction of the signal line 42.

As shown in FIG. 3B, the examining system for detecting scattering parameters comprises a network analyzer 124, a personal computer 126, a stage 128 for carrying a device, and probe heads 132 or 132a and 132b. A device including the coplanar waveguide 10 to be examined, which may merely be referred to as substrate, may be carried on the device carriage stage 128. The grounding ports Q at the ends of each ground plane 44 and the first and second ports P₁ and P₂ at the ends of the signal line 42 are connected to the network analyzer 124 by the probe heads 132a and 132b which are of a conventional coplanar form. The probe heads 132a and 132b being of the coplanar form are configured so as to be respectively connectable with the first and second ports P₁ and P₂ of the signal line 42, and simultaneously, with the grounding ports Q of the ground planes 44a and 44b. With the example of structure shown in FIG. 3A, the probe heads 132a and 132b are connected with respective left and right contact pads, seen in the figure, of the ground planes 44a and 44b.

As an example of the probe heads 132a and 132b, Air Coplanar Probe head provided by Cascade Microtech, Inc., may be applied. In addition, as the network analyzer being suitably applicable to the illustrative embodiment, which is operable in accordance with a measured frequency bandwidth is provided by, e.g. Agilent Technologies, Inc., or Anritsu Corporation.

As an index of small-signal property in a high frequency bandwidth, a scattering matrix or an S matrix defining S parameters as matrix elements may be applied. Since the S parameters are represented by the ratio in electric power component of output electric signals transmitted and reflected to an input electric signal, they can be measured even in the high frequency bandwidth. The S matrix may have two rows and two columns and be represented by the following expression (1):

$$( \begin{matrix}{b}_{1} \\ {b}_{2}\end{matrix} ) = ( \begin{matrix}{S}_{11} & {S}_{12} \\ {S}_{21} & {S}_{22}\end{matrix} ) ( \begin{matrix}{a}_{1} \\ {a}_{2}\end{matrix} ) \qquad ( 1 )$$

where the column vector components a₁ and a₂ are input electric signals and the column vector components b₁ and b₂ are output electric signals.

When both ends of the signal line 42 respectively include the first and second ports P₁ and P₂, the input signal a₁ is inputted to the first port P₁, and then, the reflected signal b₁ outputted from the first port P₁ and the transmitted signal b₂ outputted from the second port P₂ are observed to determine reflected and transmitted coefficients for the input signal a₁ as S matrix components S₁₁ and S₂₁, respectively. Similarly, the input signal a₂ is inputted to the second port P₂, and then, the reflected signal b₂ outputted from the second port P₂ and the transmitted signal b₁ outputted from the first port P₁ are observed to determine reflected and transmitted coefficients for the input signal a₂ as S matrix components S₂₂ and S₁₂, respectively. Thus, the S matrix of the coplanar waveguide is definitely determined.

In other words, the matrix elements S₁₁ and S₂₂ of the S matrix are respectively the reflected coefficients observed at the first and second ports P₁ and P₂. In addition, the other matrix elements S₁₂ and S₂₁ of the S matrix are respectively the transmitted coefficients from the first and second ports P₁ and P₂ to the second and first ports P₂ and P₁.

In the coplanar waveguide as shown in FIG. 3A, the first and second ports P₁ and P₂ are symmetrized in their pattern shapes. Therefore, except for error in measuring and disturbance from the environment, the elements S₁₁ and S₁₂ will be respectively equal to the elements S₂₂ and S₂₁. As the disturbance from the environment, there are a temperature fluctuation and noise.

In the embodiment, the frequency bandwidth is set to a range requiring small input signal, and then, the S parameters will be measured. An attenuation constant αₘ is determined by using the element S₂₁ or S₁₂ of the measured S parameters and be represented by the following expression (2):

$${α}_{m} = - 20 \cdot \frac{log ( \vert {S}_{21} \vert )}{H} \qquad ( 2 )$$

where the factor H indicates an interval between both ends of the signal line formed as the coplanar waveguide, i.e. an interval between the first and second ports P₁ and P₂, to correspond to the length of a transmission line.

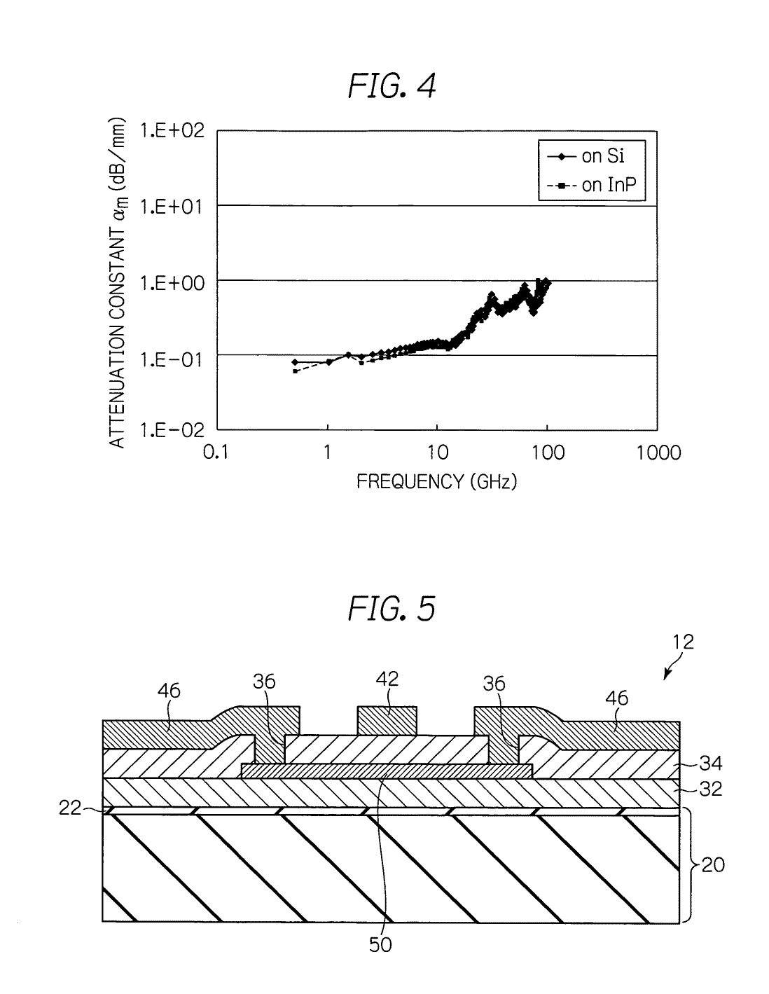

For instance, the attenuation constant αₘ determined in the above-mentioned manner will be plotted as shown in FIG. 4. FIG. 4 is a graph plotting the attenuation constants dependent upon frequency, that is, shows how the attenuation constant depends on the frequency. In the figure, the horizontal axis indicates frequency (GHz) and the vertical axis does the attenuation constant αₘ (dB/mm). The graph shows a measured result according to the illustrative embodiment of the coplanar waveguide 10 shown in FIG. 1. In FIG. 4, in case of using a high resistance silicon substrate as the substrate for the coplanar waveguide, the attenuation constant is plotted by diamond dots while in case of using the InP substrate it is done by square dots.

As seen from FIG. 4, in accordance with the illustrative embodiment, even if the inexpensive silicon substrate is applied, it is achievable to produce the coplanar waveguide having its attenuation constant comparable to a compound semiconductor substrate, such as the InP substrate.

Now, with reference to FIG. 5, an alternative embodiment of a coplanar waveguide according to the present invention will be described. FIG. 5 is a schematic cross-sectional view illustrating a coplanar waveguide 12 of the alternative embodiment.

In the coplanar waveguide 12, the ground planes 46, aligned on both sides of the central signal line 42, are electrically connected with each other by interconnections 50, which may sometimes be referred to as bridge connections. The bridge connections 50 are provided at predetermined intervals so that electrical potentials of the planes 46 are always substantially equal to each other. When the coplanar waveguide 12 is formed in straight line shape, the interval between the bridge connections 50 may be about a quarter of the wavelength of an electromagnetic wave transmitted over the signal line 42. In addition, where the signal line 42 is bent at an angle of 90°, the bridge connection 50 may be provided. The bridge connection 50 is generally formed in an air-bridge structure.

The coplanar waveguide 12 of the alternative embodiment differs from the coplanar waveguide 10 of the preferred embodiment particularly in the bridge connection electrically connecting the ground planes 46 in the insulated layer. Other components in the coplanar waveguide 12 may be similar to those in the preferred embodiment shown in and described with reference to FIG. 1 although a repetitive description will be refrained from.

In the alternative embodiment, the insulated layer of the coplanar waveguide 12 comprises first and second insulated layers 32 and 34.

As an example of the first insulated layer 32, SiN film may be formed on the amorphous silicon layer 22. The first insulated layer 32 suitably has a thickness to the extent that the bridge connection 50 mentioned below is insulated from the substrate 20, e.g. a thickness of 200 nm.

The bridge connection 50 is mounted on the first insulated layer 32 and used for electrically connecting the ground planes 46 with each other. In the alternative embodiment, a plurality of bridge connections 50 may be provided at predetermined intervals according to the shape and length of the signal line 42 and the wavelength of an electromagnetic wave to be transmitted over the signal line.

The second insulated layer 34 is mounted also on the first insulated layer 32 to cover the bridge connections 50. The second insulated layer 34 suitably has a thickness to the extent that the signal line 42 is insulated from the bridge connection 50, e.g. a thickness of 250 nm. The second insulated layer 34 is also provided with contact halls 36 exposing both ends of the bridge connections 50.

The ground planes 46 are formed on the second insulated layer 34 and have its part inserted in the contact halls 36. By such a structure, the bridge connections 50 make the ground planes 46 electrically connected with each other.

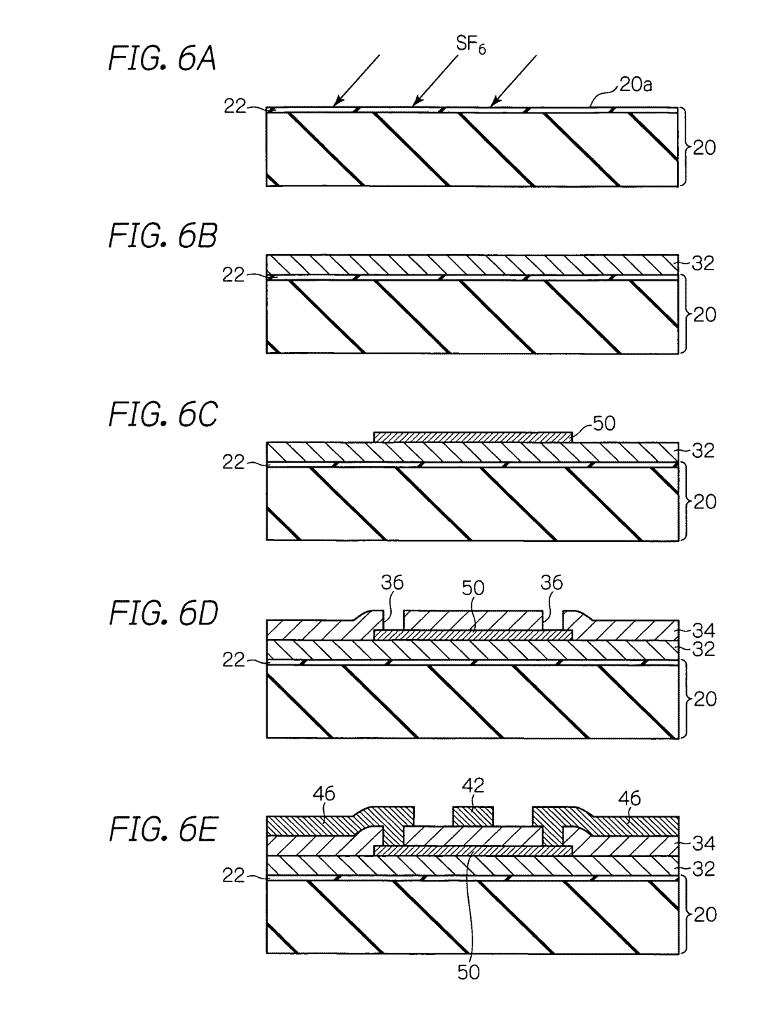

With reference to FIGS. 6A to 6E, a method of fabricating the coplanar waveguide 12 including the bridge connections 50 disposed under the signal line 42 will be described. FIGS. 6A to 6E simply show respective situations in the processes of fabricating the coplanar waveguide 12 in the form of schematic cross-sectional views.

In the method, first, at least one 20a of the primary surfaces of the high resistance silicon substrate is etched by an RIE manner using SF₆ gas for the period of two minutes. Consequently, the substrate 20 is obtained which is provided with the amorphous silicon layer 22 on its main surface 20a as shown in FIG. 6A.

Next, on the amorphous silicon layer 22, the first insulated layer 32 is formed as shown in FIG. 6B. The first insulated layer 32 may be formed by growing SiN film to a thickness of 200 nm, for example, in a plasma CVD manner.

In addition, on the first insulated layer 32, the bridge connections 50 are formed as shown in FIG. 6C. The bridge connections 50 may be formed by means of conventional lift-off manner. Namely, first, a photoresist material is applied to the first insulated layer 32. The photoresist layer is then exposed and developed to remove parts of the photoresist which will have the bridge connections 50 to be formed, thereby forming resist patterns for the bridge connections. Furthermore, onto the entire resist and insulated layer, metal film is vapor-deposited. Subsequently, the redundant resist patterns are removed by using organic solvent to complete the bridge connections 50.

After forming the bridge connections 50, on the first insulated layer 32, the second insulated layer 34 is formed to cover the bridge connections 50. The second insulated layer 34 may be formed in a similar manner to the first insulated layer 32, for example, as SiN film having a thickness of about 200 nm.

Moreover, the contact halls 36 are opened at portions of the second insulated layer 34 to expose both ends of the bridge connections 50 as shown in FIG. 6D. The contact halls 36 may be opened in a preferred chosen, conventional manner, such as photolithography or dry etching.

Next, on the second insulated layer 34, the signal line 42 and the ground planes 46 are formed so as to put the signal line between the planes. More specifically, first, a photoresist material is applied to the second insulated layer 34. The photoresist layer is then exposed and developed to remove parts of the photoresist which will have the signal line 42 and the ground planes 46 to be formed, thereby forming resist patterns for the coplanar waveguide. Furthermore, onto the insulated layer, metal film is layered by, for instance, plating. For the material of the metal film, for example, gold or Au may be applied. Subsequently, the residual resist patterns are removed by using organic solvent to complete the signal line 42 and the ground planes 46.

Portions of the ground planes 46 are formed in the contact halls 36 to be connected with the bridge connections 50 as shown in FIG. 6E. Consequently, the bridge connections 50 make the ground planes 46 electrically connected with each other.

Furthermore, on the second insulated layer 34, a protect film, such as SiN film, not shown, may be deposited to cover the signal line 42 and the ground planes 46.

Conventionally, the bridge connection having an air-bridge structure is formed by plating. Therefore, two steps of plating were wastefully necessary for a process of forming the signal line and the ground planes and for another process of forming the bridge connections. The two plating steps thus caused increase of time and cost required for the production.

Moreover, in a general coplanar waveguide, the surfaces of the signal line and the ground planes were positioned higher than the surface of the substrate. Therefore, in case of forming the bridge connections after forming the signal line and the ground planes, the air-bridge structure would be formed at positions where a stepwise difference in level is larger. This difference would make the bridge connections hung down between the signal line and the ground plane, thereby inducing a larger parasitic capacitance so as to cause signal loss.

In addition, in order to carry out the photolithography on such a larger stepwise difference in level, it is necessary to optimize a coefficient of viscosity and requirements for applying photoresist material as well as time and temperature control required for reflow processes, which may render it difficult to implement the photolithography.

By contrast, in accordance with the manufacturing method described with reference to FIGS. 6A through 6E, the bridge connections are formed beneath the signal line and the ground planes. That makes it possible to fabricate the bridge connections not by plating but by vapor deposition. Consequently, one plating step is enough, thereby preventing the manufacturing time and cost from increasing.

Moreover, in accordance with the manufacturing method, the bridge connections 50 are not made hung down between the signal line 42 and the ground planes 46. That makes the parasitic capacitance component caused by the bridge connection smaller than the air-bridge structure.

In addition, in the manufacturing method, the photolithography is carried out not at the positions where a stepwise difference in level is larger, thus being easily implemented.

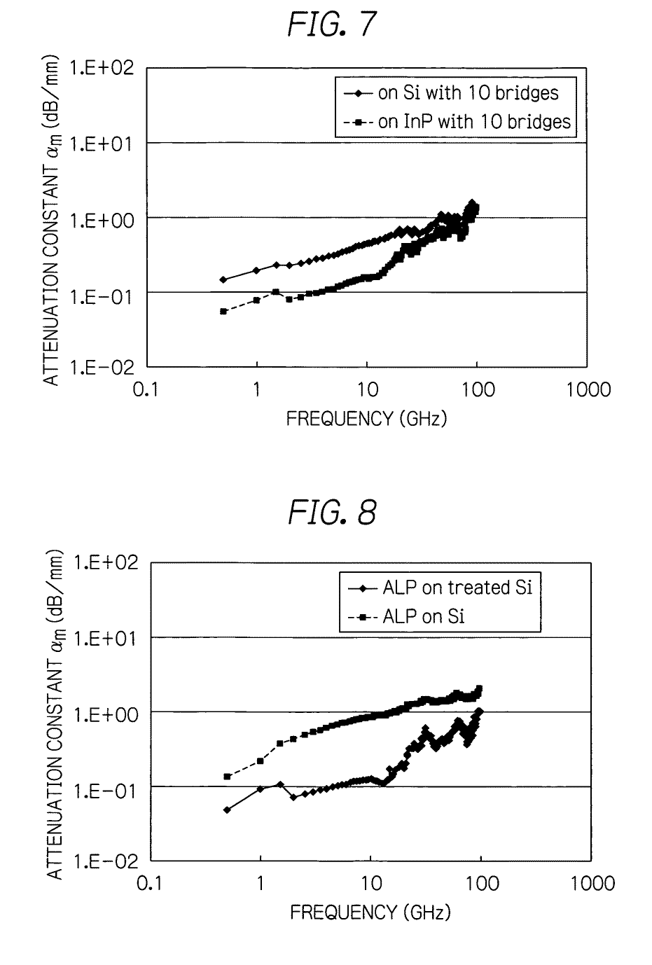

Next, with reference to FIG. 7, the attenuation constant of the coplanar waveguide 12 in the alternative embodiment will be described. FIG. 7 is a graph plotting the attenuation constants with respect to frequency, that is, shows the characteristic of the attenuation constant depending on the frequency. In FIG. 7, the horizontal axis indicates frequency (GHz) and the vertical axis does the attenuation constant αₘ (dB/mm). The graph of FIG. 7 shows a measured result according to the alternative embodiment of the coplanar waveguide 12. In the figure, in case of using the high resistance silicon substrate as the substrate for the coplanar waveguide, the attenuation constant is plotted by diamond dots while in case of using the InP substrate it is done by square dots. The attenuation constants shown in FIG. 7 are measured in case where the length of the signal line 42 is 1570 μm and ten bridge connections are provided.

As seen from FIG. 7, in accordance with the alternative embodiment, although the inexpensive silicon substrate may fall short of the InP substrate, the attenuation constant in applying the inexpensive silicon substrate is maintained less than 1 db/mm in the low frequency bandwidth. In addition, in the frequency bandwidth around 100 GHz, the inexpensive silicon substrate can achieve the similar attenuation constant to the InP substrate.

Incidentally, a further alternative embodiment of a coplanar waveguide according to the present invention will be described. As the insulated layer, SiN or SiO₂ film is used in the above-mentioned embodiments. However, the further alternative embodiment may use fluorocarbon coating resin, such as AL-Polymer (trade name) manufactured by Asahi Glass co., Ltd., having photosensitivity and low dielectric constant.

The film formed of the AL-Polymer, in case of being thicker, may expand by reacting to organic solvent and emit excessively gas in baking process for degasification. In this case, for instance, a silicon nitride film formed directly on the AL-Polymer layer may be blasted.

By contrast, in another case where the film formed of the AL-Polymer is as thin as 1 μm or less, even if the AL-Polymer film is immersed in a solution, only a little solution permeates the AL-Polymer, thus gas emitted in baking process for degasification being reduced. It is therefore possible to prevent the blast of the silicon nitride film. However, the AL-Polymer film being 2 μm or less activates a low resistant layer between the film and a high resistance silicon substrate so as to deteriorate its attenuation constant.

Accordingly, a substrate having an amorphous silicon layer is used to form the insulated layer of the AL-Polymer on the amorphous silicon layer, thereby preventing of the activation of the low resistant layer. Namely, even if the film thickness is as thin as 1 μm or less, the good attenuation constant can be obtained.

Next, with reference to FIG. 8, the attenuation constant of the coplanar waveguide in the further alternative embodiment will be described where the insulated layer is formed of the AL-Polymer. FIG. 8 is a graph plotting the attenuation constants with respect to frequency, that is, shows the characteristic of the attenuation constant depending on the frequency. The horizontal and vertical axes in FIG. 8 respectively indicate frequency (GHz) and the attenuation constant αₘ (dB/mm). In the figure, in case of using the high resistance silicon substrate including the amorphous silicon layer as the substrate for the coplanar waveguide, the attenuation constant is plotted by diamond dots. In the high resistance silicon substrate, for instance, the first insulated layer 32 is formed of the AL-Polymer having thickness of 0.65 μm and the second insulated layer 34 is formed of laminated SiON film having thickness of 250 nm and SiN film having thickness of 20 nm.

On the other hand, in case of using the substrate not including the amorphous silicon layer, the attenuation constant is plotted by square dots. In such a substrate, for instance, the first insulated layer 32 is formed of the AL-Polymer having thickness of 0.65 μm and the second insulated layer 34 is formed of laminated SiON film having thickness of 250 nm and SiN film having thickness of 20 nm, too.

As seen from FIG. 8, when the amorphous silicon layer is formed on the high resistance silicon substrate, the good attenuation constant can be obtained in comparison with a case of having no amorphous silicon layer.

The entire disclosure of Japanese patent application No. 2009-190981 filed on Aug. 20, 2009, including the specification, claims, accompanying drawings and abstract of the disclosure, is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. A coplanar waveguide comprising:
a high resistance silicon substrate having one primary surface on which an amorphous silicon layer is formed;
an insulated layer provided on said amorphous silicon layer;
a signal line arranged on said insulated layer; and
a pair of ground planes arranged on said insulated layer so as to put said signal line between said planes.

2. The coplanar waveguide in accordance with claim 1, further comprising a bridge connection formed in said insulated layer for electrically connecting said ground planes with each other.

3. The coplanar waveguide in accordance with claim 1, wherein the insulated layer is formed of a silicon nitride film.

4. The coplanar waveguide in accordance with claim 1, wherein said insulated layer includes coating resin of fluorine series having photosensitivity and low dielectric constant.

5. The coplanar waveguide in accordance with claim 4, wherein the coating resin is fluorocarbon.

6. A method of fabricating a coplanar waveguide, comprising the steps of:
forming an amorphous silicon layer on one primary surface of a high resistance silicon substrate;
forming an insulated layer on said amorphous silicon layer; and
arranging a signal line and a pair of ground planes on said insulated layer so as to put said signal line between the planes.

7. A method of fabricating a coplanar waveguide, comprising the steps of:
forming an amorphous silicon layer on one primary surface of a high resistance silicon substrate;
forming a first insulated layer on said amorphous silicon layer;
arranging a bridge connection in said first insulated layer;
forming a second insulated layer on said first insulated layer to cover said bridge connection;
opening a pair of contact halls in said second insulated layer to partially expose said bridge connection; and
arranging a signal line and a pair of ground planes on said insulated layer so as to put said signal line between the planes,
whereby said bridge connection makes said pair of ground planes electrically connected with each other.
